(19) United States
(12) Patent Application Publication
(10) Pub. No.: US 2007/0126618 A1
(43) Pub. Date: Jun. 7, 2007

(54) DISPLAY DEVICE DRIVE DEVICE, DISPLAY DEVICE, AND DRIVE DEVICE OR DISPLAY DEVICE CHECK METHOD

(75) Inventors: Yoshito Tanaka, Nagasaki (JP); Mitsunori Katsu, Nagasaki (JP)

Correspondence Address: CONNOLLY BOVE LODGE & HUTZ LLP, P.O. BOX 2207, WILMINGTON, DE, 19899-2207, US

(73) Assignee: Test Research Laboratories Inc., Nagasaki (JP)

(21) Appl. No.: 11/164,687

(22) Filed: Dec. 1, 2005

(51) Int. Cl. H03M 1/12

(52) U.S. Cl. 341/155

(57) ABSTRACT

A display device drive device includes a signal processing section (20) for correcting an input digital image signal and outputting a digital corrected signal, an analog signal output section (30) for outputting an analog image signal to a plurality of image output terminals (1), a signal switching selection (40) for successively selecting an analog image signal from the analog signal output section (30), and a delta/sigma modulator (9) for delta/sigma-modulating the analog image signal selected by the signal switching section (40) and feedback-inputs the created 1-bit digital modulated signal to the signal processing section (20). The signal processing section (20) successively outputs initial output data Vᵢₙᵢₜ₀ to Vᵢₙᵢₜₘ to the analog signal output section (30), receives a modulated signal for the initial output data Vᵢₙᵢₜ₀ to Vᵢₙᵢₜₘ from the delta/sigma modulator (9) so as to calculate correction data. Thus, even if irregularities are caused in the non-linear electric characteristic between output terminals in the display drive LSI of ultra-multi-pin output, it is possible to sufficiently correct them with a high accuracy.

### BACKGROUND OF THE INVENTION

1. Field of the Invention

The present invention relates to a drive device having a great many analog output terminals like LSI for driving a display device, a display device using the drive device, and a check method for the drive device or display device.

2. Description of the Related Art

Many display devices such as a liquid crystal device, an organic EL display device, a plasma display and a surface-conduction electron-emitter display (SED) respectively processes image data with an electronic circuit such as a drive circuit and outputs the processed data from a plurality of output terminals provided on the drive circuit to a display element. A drive transistor disposed so as to meet the respective output terminals of the drive circuit has no few variances in electric characteristics, therefore the variances occur in signal values outputted from the respective output terminals.

For example, the variance in the drive transistor causes a mismatch in transistor characteristics, so that offset errors or gain errors occur. Further, a systematic error in circuit characteristics appears due to the variation in the production process. To correct such variances, a variety of technologies as disclosed in Patent Documents 1 to 3 have been proposed.

Patent Document 1: Japanese Patent Laid-Open No. 2000-307424.

Patent Document 2: Japanese Patent Laid-Open No. 2002-366119.

Patent Document 3: Patent Publication No. 3199827.

The prior art disclosed in Patent Document 1 relates to an electronic circuit for converting a digital input signal into an analog output signal and outputting the converted signal to a display element. The electronic circuit includes a latch circuit for storing an inputted digital signal, a memory circuit for storing offset correction data, an addition circuit for adding the offset correction data to the inputted digital signal, and a D/A converter for converting an outputted signal from the addition circuit into an analog signal.

In Patent Document 1, a correction circuit is separately provided to measure an offset amount of each D/A converter and convert the offset amount into offset correction data. The correction circuit is constituted of a comparator for comparing an analog output signal of the D/A converter corresponding to each output terminal with an analog output signal of the D/A converter provided in the correction circuit, and an encoder circuit for generating digital offset correction data using the output data of the comparator. Each memory circuit stores as offset correction data, a difference between an output signal from the D/A converter corresponding to each output terminal and an output signal from the D/A converter serving as the basis thereof, therefore digital signals corrected by the correction data have the same level at each output terminal.

In Patent Document 2, there is shown a circuit for correcting variances with a contrast table provided for a plurality of analog circuits. The prior art disclosed in Patent Document 2 relates to a liquid crystal display device. A picture signal control circuit in a display controller includes an A/D converter for converting an analog input signal to a display controller into a digital signal, a signal processing circuit for performing signal processing of a digital signal, a contrast table for storing correction data, and a D/A converter for converting a digital signal corrected by the contrast table into an analog signal. The contrast table and the D/A converter are provided for each phase. Such a configuration permits variances to be corrected for each phase with the contrast table.

In Patent Document 3, there is disclosed a prior art of correcting an input signal to a drive circuit using a single outputted from a check terminal. According to this prior art, display image signals of various types of test patterns are previously inputted into the drive circuit and an output signal corresponding to the inputted signal is sequentially selected. The sequentially selected signal is outputted from the check terminal to an A/D converter, and correction data obtained based on a digital signal outputted from the A/D converter are stored in a memory element. The correction data permits an input signal into the drive circuit to be corrected.

Generally, variances in the electrical characteristics of a transistor have serious influences onto variances in the number of impurities implanted in the course of a semiconductor process or in transistor sizes due to unevenness of etching, or onto a channel length modulation effect caused by reducing the transistor size.

Referring now to FIGS. 19 and 20, there is described an effect of a change in a channel length L onto transistor characteristics. When the channel length L of the transistor is significantly large, as illustrated in FIG. 19A, a drain current I_{D} is roughly constant as indicated by a full line regardless of the magnitude of a drain-source voltage V_{DS}. However, when the channel length L of the transistor is small, an influence of a channel length modulation effect occurs, and the drain current I_{D} increases as indicated by a broken line in proportion to the magnitude of the drain-source voltage V_{DS}. This effect increases more as a gate-source voltage V_{GS} is higher.

FIG. 19B shows such transistor characteristics from a relationship between the gate-source voltage V_{GS} and the drain current I_{D}. That is, when a channel length L is large, the drain current I_{D} is roughly constant regardless of a change in a drain-source voltage V_{DS} if the gate-source voltage V_{GS} is constant. On the contrary, when the channel length L is small, the drain current I_{D} changes largely with a change of the drain-source voltage V_{DS}. Therefore, an operational amplifier using a transistor having a small channel length L will produce a non-linear effect. For example, a voltage follower circuit as shown in FIG. 20A will produce non-linearity as shown in FIG. 20B against a theoretical value. As shown in FIG. 20B, when the channel length L is large, the relationship between input voltage and output voltage is linear so as to roughly meet the theoretical value, while when the channel length L is small, it is non-linear and deviates from the theoretical value.

The channel length modulation effect resulting in non-linearity can be suppressed by increasing the channel length L. Since variance in the number of impurities introduced into a transistor is influenced by statistical fluctuations, the variance can be reduced by increasing the area of the transistor. Moreover, variance in etching can be reduced by increasing the peripheral length of the transistor. Therefore, to reduce variance in the electrical characteristics of the transistor, it is effective to increase the size of the transistor.

Generally, a semiconductor circuit which outputs an image signal as typically found in a drive LSI for a display device though multi-pin terminal has used a large-sized transistor to suppress variance in outputted values. Especially, if the channel length L is small, the characteristics of the transistor themselves becomes worse due to an influence of a channel length modulation effect or the like, therefore a highly precise LCD drive circuit has used a large-sized transistor until now. For example, even if the drive circuit is in 0.18 μm process, a large drive transistor having a channel length L of 4 μm and a channel width W of approx. 100 μm is used. Moreover, even a D/A converter of the drive circuit usually uses a large-sized transistor having a channel length L of approx. 3 μm to suppress variance in characteristics.

In forming a voltage follower circuit out of an operational amplifier in place of a source follower transistor in the drive circuit, an operational amplifier or a D/A converter using a large-sized transistor is used to suppress variance in characteristics. In forming a drive circuit out of an analog signal switching device (a multiplexer) and a gradation voltage source, a transistor having a large channel length L is used to increase the accuracy of the gradation voltage source. In this case, to equalize a voltage drop (impedance), the multiplexer is designed so that the number of transistor switches used from a power supply is the same. However, a voltage drop in proportion to a distance from a power supply or a voltage drop due to variance in transistors is unavoidable.

With trends toward use of super-multiple pins in a drive LSI and miniaturization of an LSI manufacturing process, miniaturization of transistors used in the LSI is now in increasing demand. At the same time, the accuracy of an analog signal is also on a request. However, the miniaturization of transistors would cause non-linearity of a circuit due to degradation of transistor characteristics as described, thus making it impossible to ensure accuracy only by linear correction using an offset constant or a gain constant. Therefore, there exists the following problem: linear correction assuming only offset variance as disclosed in Patent Document 1 would provide no sufficient correction of variance in non-linear characteristics generated in using a small-sized transistor.

In the prior art of correction disclosed in Patent Document 2, setting of correction data is made while a displayed screen is being observed and evaluated, which causes the following disadvantage: the dependence on human eyes or use of a large-scaled system such as an image pickup apparatus is required.

The prior art disclosed in Patent Document 3 converts an analog signal outputted from a drive LSI into a digital signal with an A/D converter and inputs the signal into a correction circuit. Simple conversion of an analog value into a digital value with the A/D converter requires a great many signal lines, thus causing a problem that the scale of a circuit becomes larger. The A/D converter and the correction circuit are outside the drive LSI, therefore an analog signal is apt to have a noise component by the time the signal is inputted into the A/D converter after being outputted from the drive LSI, thus causing a problem that highly accurate correction is difficult to perform.

### SUMMARY OF THE INVENTION

In view of the aforementioned problems, it is an object of the present invention to sufficiently correct variances in nonlinear electrical characteristics generated between the respective output terminals even if a display drive LSI of super-multiple pins output uses a small-sized transistor.

It is another object of the present invention to correct, with high accuracy, variances in nonlinear electrical characteristics generated between the respective output terminals in a display drive LSI of super-multiple pins output.

It is another object of the present invention to minimize a circuit configuration for correcting variances in nonlinear electrical characteristics generated between the respective output terminals in a display drive LSI of super-multiple pins output.

To achieve the aforementioned object, a display device drive device of the present invention comprises: a signal processing section for inputting digital signals corresponding to the plurality of output terminals and correcting each of the digital signals in accordance with correction data corresponding to the magnitude of the signal to output a digital correction signal; an analog signal output section for producing an analog signal based on the digital correction signal outputted from the signal processing section and outputting the analog signal to each of the plurality of output terminals; a signal switching section which is connected to the plurality of output terminals and sequentially selects the analog signal from the analog signal output section; and a delta/sigma modulation section for applying delta/sigma modulation to the analog signal selected by the signal switching section and outputting a 1-bit digital modulated signal subjected to the delta/sigma modulation to the signal processing section. The signal processing section includes a function of sequentially outputting a reference digital signal having a plurality of stages of magnitudes to the analog signal output section, inputting the 1-bit digital modulated signal corresponding to the reference digital signal from the delta/sigma modulation section for demodulation and calculating correction data based on the demodulated signal and the reference digital signal, and a function of making a correction based on the correction data.

Since the present invention calculates correction data based on the reference digital signal of the plurality of stages and a digital signal of a plurality of stages obtained by digitalizing an analog signal produced from the reference digital signal, correction data incorporating nonlinear output characteristics can be calculated, unlike simple linear correction using an offset constant or a gain constant. Therefore, even in the case of use of a small-sized transistor in the display drive LSI of super-multiple pins output, resulting variance in nonlinear electrical characteristics can be corrected sufficiently in accordance with the magnitude of an input digital signal.

The present invention can measure an output signal with remarkably high accuracy by suppressing quantization noise, using the delta/sigma modulation section, thus generating highly accurate data. An output from the delta/sigma modulation section is a 1-bit digital modulated signal from one output terminal, therefore the output can reduce the number of wirings and miniaturize an apparatus.

The signal processing section may be configured so as to calculate an approximated curve based on a change in a demodulation signal relative to the reference digital signal having magnitudes of a plurality of stages and to calculate correction data based on the approximated curve. This configuration provides high resolution relative to the magnitude of an input digital signal and accurate correction data, thus conducting highly accurate correction.

Moreover, the signal processing section may be configured so as to calculate correction data using an average value of a plurality of demodulation signals produced by outputting the reference digital signals having the magnitudes of the plurality of stages over a plurality of times. This configuration can reduce random noises included in an output signal measured when the reference digital signal is inputted, and can calculate correction data with fewer errors.

The correction data may be generated respectively, being corresponding to a plurality of output terminals. Usually, there are variances in electrical characteristics between circuits corresponding to the respective output terminals. Accordingly, by calculating the correction data in accordance with the respective output terminals respectively, a correction can be made with higher accuracy.

The delta/sigma modulation section may be configured so that setting of clock speed can be changed. This configuration can change the clock speed in accordance with required correction accuracy. For example, by increasing the clock speed, an S/N ratio of a signal can be improved. This can yield higher flexibility in the accuracy of correction data to be produced than a case where an analog output signal from an output terminal is simply fed back to a correction signal processing circuit through an A/D converter, thus calculating correction data with appropriate accuracy.

Moreover, the delta/sigma modulation section may includes a delta/sigma modulation output terminal capable of outputting a 1-bit digital modulated signal from the delta/sigma modulation section. This configuration can externally detect an analog signal to be outputted from the output terminal through a delta/sigma modulation output terminal, and can externally inspect and evaluate a drive device. The signal outputted from the delta/sigma modulation output terminal is a 1-bit digital modulated signal, which can restrain the degradation in signal accuracy due to noise more than a case where an analog signal is outputted. Furthermore, the output of one delta/sigma modulation section needs only one electric wire, accordingly even if the number of output terminals is very large, the characteristics of the output signals can be inspected and evaluated by connecting with the one delta/sigma modulation output terminal, thus eliminating need of a complicated and expensive test system corresponding to super-multiple pins. An inspection apparatus receiving the 1-bit digital modulated signal can be made to serve as a simple digital tester for performing digital signal processing, thus eliminating need of an analog tester.

A drive device configured in the above way may be formed on the identical semiconductor IC. This configuration can calculate correction data using highly accurate data which are highly resistant to noise invasion by assembling the signal processing section for calculating and storing the correction data into a drive device, thus improving correction accuracy. In other words, the output signal from the output terminal will passes through only a one-chip drive device and will not pass through external wiring, which makes it difficult for noises to invade into the output signal. Inspecting and evaluating a drive device can be done including a signal processing section equipped with a correction function, thus need of check of a circuit having a correction function can be eliminated, thus reducing manufacturing cost as the whole.

Preferably, a display device is configured by using such a drive device as described above. This configuration performs display drive with an output signal corrected by highly accurate correction data as described above, thus improving the quality of a displayed image, as well as highly accurate check and evaluation with the drive device assembled. Moreover, correction is performed with the drive device assembled into the display device, thereby correcting variances including manufacturing variance, environmental variance and aging variance in the whole display device.

According to the present invention, even if nonlinear variance in electrical characteristics occurs between respective output terminals in display drive LSI of super-multiple pin outputs by using of a small-sized transistor, sufficient and highly accurate correction of a nonlinear error can be performed. Thus, image outputs having small variance can be obtained, and highly accurate check and evaluation for electrical characteristics can be performed with digital signals from a small amount of output terminals. Moreover, a circuit configuration required therefor can be minimized.

### BRIEF DESCRIPTION OF THE DRAWINGS

FIG. 1 is a block diagram illustrating a configuration of a liquid crystal display device according to one embodiment of the present invention;

FIG. 2 is a view illustrating an arrangement of terminals of a drive device according to one embodiment of the present invention;

FIG. 3 is a block diagram illustrating a circuit configuration example of a drive device according to one embodiment of the present invention;

FIG. 4A and 4B are a view illustrating a relationship between an input signal and an output signal into/from a delta/sigma modulator according to one embodiment of the present invention;

FIG. 5 is a view illustrating a configuration example of initial output data defined by a correction signal processing circuit in generating correction data;

FIG. 6 is a view illustrating a configuration example of measurement data measured by a delta/sigma modulator in generating correction data;

FIG. 7 is a view illustrating a configuration example of correction data stored in a correction data storage circuit;

FIG. 8 is a view illustrating another configuration example of correction data stored in a correction data storage circuit;

FIG. 9 is a view illustrating a configuration example of decimation filters built in a correction signal processing circuit and a simplified tester according to one embodiment of the present invention;

FIG. 10 is a view illustrating an example of results of decimation processing and averaging processing of 1-bit digital modulated signal outputted from a delta/sigma modulator with a correction signal processing circuit.

FIG. 11 is a view illustrating a configuration example of an approximated curve factor data stored in a correction data storage circuit;

FIG. 12 is a view illustrating a configuration example of a test system in checking and evaluating a wafer having a drive device according to one embodiment of the present invention;

FIG. 13 is a view illustrating a configuration example of a test system in checking and evaluating a liquid crystal display device mounted with a drive device according to one embodiment of the present invention;

FIG. 14 is a block diagram illustrating another circuit configuration of a drive device according to one embodiment of the present invention;

FIG. 15 is a block diagram further illustrating another circuit configuration of a drive device according to one embodiment of the present invention;

FIG. 16A and 16B are a view of a configuration example of measurement data measured by a delta/sigma modulator in generating correction data with a drive device using a gradation voltage source.

FIG. 17 is a view illustrating a configuration example of correction data for global correction stored in a correction data storage circuit with a drive device using a gradation voltage source.

FIG. 18 is a view illustrating a configuration of a conventional test system.

FIG. 19A and 19B are a view for illustrating an influence of a change in the size of channel length onto transistor characteristics; and

FIG. 20A and 20B are a view illustrating an influence of a change in the size of channel length onto transistor characteristics.

### DETAILED DESCRIPTION OF PREFERRED EMBODIMENTS

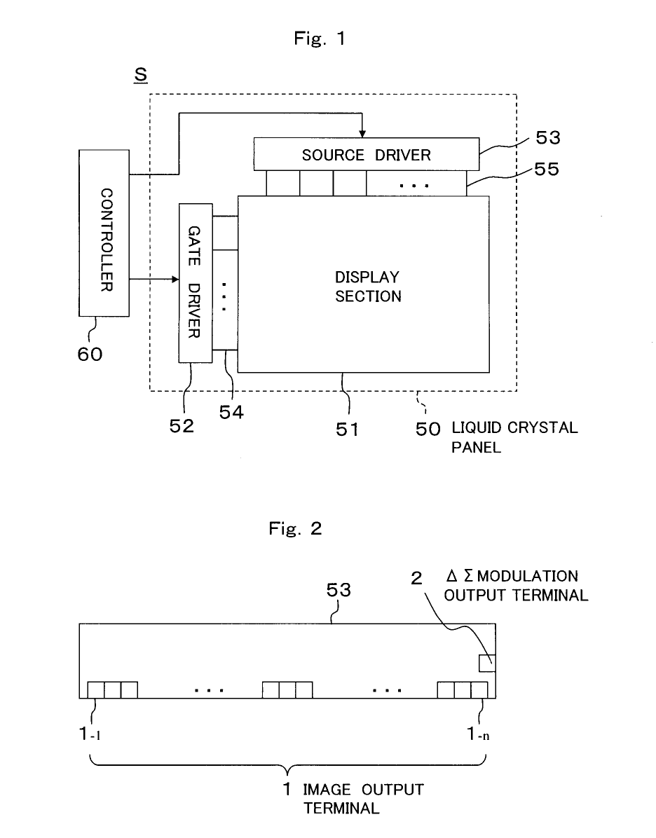

Reference will now be made in detail to embodiments of the present invention, examples of which are illustrated in the accompanying drawings. FIG. 1 is a block diagram illustrating a configuration of a liquid crystal display device S according to this embodiment. As illustrated in FIG. 1, the liquid crystal display device S according to this embodiment is constituted of a liquid crystal panel (a liquid crystal display element) 50 and a controller 60 for controlling a display of an image by the liquid crystal panel 50.

The liquid crystal panel 50 is constituted of a display section 51 formed with a pixel section in a matrix manner, a drive device (a gate driver LSI) 52 for a scanning signal wire and a drive device (a source driver LSI) 53 for an image signal wire. The drive devices 52, 53 are disposed on the identical substrate to the display section 51. On the display section 51, a plurality of scanning signal wires 54 and a plurality of image signal wires 55 orthogonal to the scanning signal wires 54 are disposed. At an a point of intersection thereof, a pixel section is disposed respectively. Ends of the scanning signal wires 54 and the image signal wire 55 are connected to output terminals of the drive devices 52, 53 respectively.

The controller 60 receives a display signal (an image signal), a clock signal, a timing signal, a horizontal synchronizing signal, a vertical synchronizing signal and so on from an external apparatus such as a personal computer, outputs a control signal to drive devices 52, 53 respectively, and outputs the display signal to the drive device 53. The drive devices 52, 53 operates based on these signals, and the drive device 53 supplies an analog image signal to each pixel section (a panel pixel group) of the liquid crystal panel 50 in accordance with a driving cycle of a scanning electrode by the drive device 52.

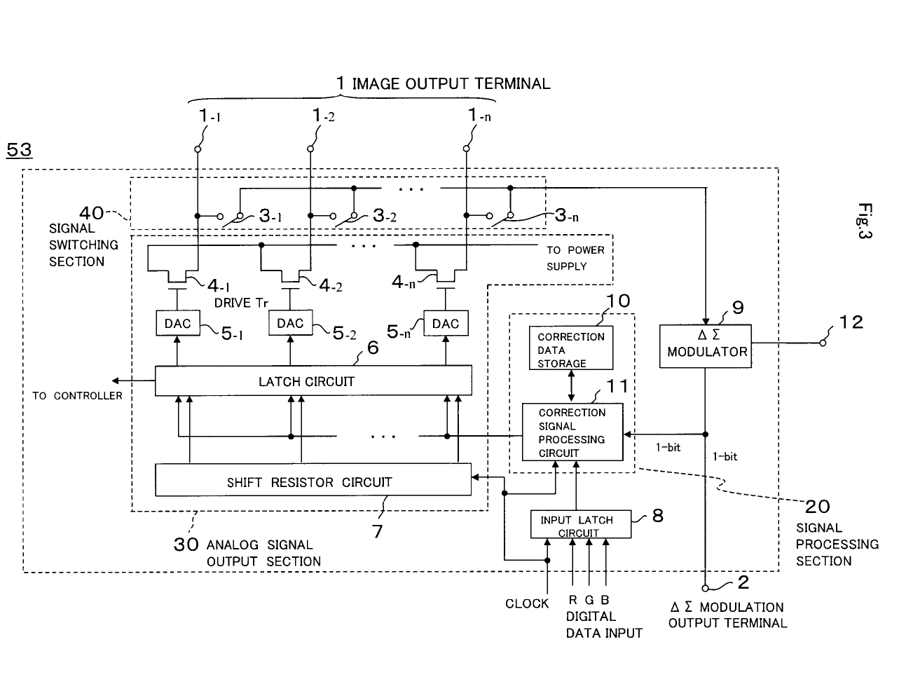

FIG. 2 is a view illustrating an arrangement of terminals of the drive device 53. As illustrated in FIG. 2, the drive device 53 includes a plurality of image output terminals 1 (1₋₁ to 1₋ₙ) for supplying an analog image signal to the external panel pixel group and the delta/sigma modulation output terminal (a check terminal) 2 for outputting a 1-bit digital modulation signal produced by applying delta/sigma modulation to the analog image signal to the outside of the drive device 53.

FIG. 3 is a block diagram illustrating a circuit configuration example of the drive device 53. As illustrated in FIG. 3, the drive device 53 is constituted of an input latch circuit 8, a delta/sigma modulator 9, a signal processing section 20, an analog signal output section 30 and a signal switching section 40. The drive device 53 configured in this way is packaged as a one-chip IC.

The input latch circuit 8 inputs a digital image signal displayed on the liquid crystal panel 50 and a clock signal. The signal processing section 20 corrects a digital image signal inputted from an input latch circuit 8. The signal processing section 20 is constituted of a correction data storage circuit 10 for storing correction data and a correction signal processing circuit 11 for correcting the digital image signal supplied from the input latch circuit 8 with correction data to output a digital correction signal.

The analog signal output section 30 receives a digital correction signal produced by the signal processing section 20, converting the digital correction signal into analog signal, and outputs the signal to an image output terminal 1. The analog signal output section 30 is constituted of a latch circuit 6 for storing a digital correction signal outputted from the correction signal processing circuit 11, being corresponding to a plurality of image output terminals 1₋₁ to 1₋ₙ, a shift register circuit 7, a plurality of D/A converters 5 (5₋₁ to 5₋ₙ) for D/A converting an output signal from the latch circuit 6, and a plurality of drive transistors 4 (4₋₁ to 4₋ₙ) for driving a data electrode of a liquid crystal panel element with the D/A converted analog image signal. This configuration may use a voltage follower circuit in place of the drive transistor 4.

Correction data stored in the correction data storage circuit 10 are used to correct variances in electrical characteristics of respective transistors, such as drive transistors 4₋₁ to 4₋ₙ and transistors for D/A converters 5₋₁ to 5₋ₙ, positioned in the drive device 53 and variances in electrical characteristics of the display section 51. Correction data used for correction and check of the drive device 53 itself are the data for correcting errors due to variances in electrical characteristics of the respective transistors in the drive circuit 53. On the other hand, correction data used for correcting or checking in such a condition that the drive device 53 is mounted on the liquid crystal display device S are the data for correcting errors due to variances in electrical characteristics of the respective transistors positioned in the drive device 53 as well as variances in electrical characteristics of TFT transistors or capacitance in the display section 51. Such correction data are constituted of a correction amount to be corrected for the digital image signal inputted into the input latch circuit 8. The correction signal processing circuit 11 reads out, from the correction data storage circuit 10, the data of the correction amount corresponding to the magnitude (equivalent to the level obtained by digitalizing the voltage value of an image signal) of a digital image signal supplied from the input latch circuit 8 and subtract the correction amount from the digital image signal to produce a digital correction signal.

The signal switching section 40 is connected between the analog signal output section 30 and the image output terminal 1. The signal switching section 40 consists of analog switches 3 (3₋₁ to 3₋ₙ) formed out of a plurality of transistors disposed so as to be corresponding to each of the respective image output terminals 1₋₁ to 1₋ₙ. The respective analog switches 3_{-1 to 3}₋ₙ sequentially operate synchronously with a storage operation of a digital correction signal into the latch circuit 6 and sequentially selects analog image signals (potentials of the respective image output terminals 1₋₁ to 1₋ₙ) to the respective image output terminals 1₋₁ to 1₋ₙ from the analog signal output section 30 and outputs the signal to the delta/sigma modulator 9.

The delta/sigma modulator 9 is constituted of an integrator, a comparator, and a 1-bit D/A converter. An analog image signal sequentially supplied from the signal switching section 40 undergoes delta/sigma modulation at a predetermined clock speed, and the obtained 1-bit digital modulated signal is outputted from one output terminal to the signal processing section 20 and a delta/sigma modulation output terminal 2.

A clock interval of the delta/sigma modulator 9 is much smaller than a Nyquist interval and is much wider in a signal frequency band than an ordinary A/D converter. The delta/sigma modulator 9 according to this embodiment is configured so that a clock signal can be changed and set from a high speed to a low speed (however, much larger than the Nyquist interval) by inputting a control signal from an external control terminal 12. The clock speed of the delta/sigma modulator 9 uses an arbitrary value predetermined according to accuracy at the time of ordinary operation of the drive device 53.

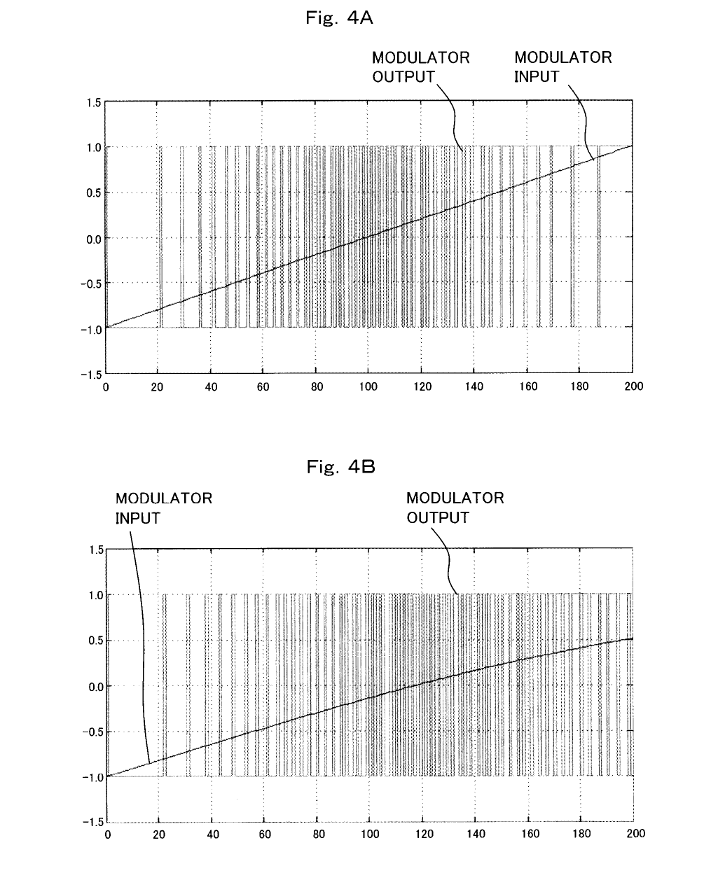

FIG. 4A and 4B are a view illustrating a relationship between an input signal and an output signal into/from the delta/sigma modulator 9. In FIG. 4A, the input signal is an analog voltage roughly linearly changing over time. The input signal indicates a signal inputted into the delta/sigma modulator 9 in a case where the size of a transistor being used is large and variance in electrical characteristics existing in the drive device 53 or the display section 51 is small, or a case where the variance in electrical characteristics existing in the drive device 53 or the display section 51 is significantly corrected. On the other hand, the input signal illustrated in FIG. 4B indicates a case where the size of a transistor being used is small and variance in electrical characteristics existing in the drive device 53 or the display section 51 occurs, thereby yielding nonlinear characteristics.

Between a case where an ideal signal without strains is inputted into the delta/sigma modulator 9 and a signal with nonlinear strains is inputted, a completely different 1-bit digital modulated signal is outputted from the delta/sigma modulator 9. That is, a 1-bit digital modulated signal in accordance with nonlinear strain can be achieved by the delta/sigma modulator 9. Accordingly, an analog image signal outputted from a plurality of image output terminals 1₋₁ to 1₋ₙ undergoes delta/sigma modulation with the delta/sigma modulator 9, and the obtained 1-bit digital modulated signal is supplied to the signal processing section 20, thus generating correction data in accordance with output values of the image output terminals 1₋₁ to 1₋ₙ as described later. Moreover, by outputting the 1-bit digital modulated signal to the outside from the delta/sigma modulation output terminal 2, the drive device 53 and the display section 51 can be checked and evaluated.

The drive device 53 can transmit, to a controller 60, the data of variances in electrical characteristics and failure (beyond a correctable range) of the drive device 53 itself and the drive transistor 4 and the D/A converter 5. That is, an output of the correction signal processing circuit 11 is inputted into the latch circuit 6, and the latch circuit 6 is connected to a data bus of the controller 60. The controller 60 can measure a voltage value of the image output terminal 1 using the data supplied from the latch circuit 6. By connecting the display section 51 to the image output terminal 1, the variances in electrical characteristics and failure of the display section 51 can be measured with the controller 60.

There is next shown the whole operation of the drive device 53 according to this embodiment configured as described above. A digital image signal and a clock signal supplied from the controller 60 are inputted into the input latch circuit 8 and stored. The digital image signal stored in the input latch circuit 8 is transmitted to the correction signal processing circuit 11 in synchronization with the clock signal.

In the correction signal processing circuit 11, digital image signal correction is performed, being corresponding to the respective image output terminals 1₋₁ to 1₋ₙ, using the correction data (a calculation method thereof is described later) stored in correction data storage circuit 10, thus producing a digital correction signal. The shift register circuit 7 sequentially output a pulse to the latch circuit 6 based on a clock signal and a shift start signal (not illustrated). The digital correction signal is sequentially stored in the latch circuit 6 in accordance with the pulse output and is distributed to each of the image output terminals 1₋₁ to 1₋ₙ, being compatible therewith.

The digital correction signal outputted from the latch circuit 6 is made into an analog image signal through the D/A converters 5₋₁ to 5₋ₙ and the drive transistors 4₋₁ to 4₋ₙ, and the analog image signal is outputted from the image output terminals 1₋₁ to 1₋ₙ to the respective pixel sections of the display section 51. At the time of ordinary operation, the delta/sigma modulator 9 comes into no action, and the analog switches 3₋₁ to 3₋ₙ of the signal switching section 40 are all in a non-selective state.

In generating correction data and checking and evaluating a drive device 53 and the display section 51, an analog image signal outputted into the image output terminals 1₋₁ to 1₋ₙ is sequentially selected by the analog switches 3₋₁ to 3₋ₙ of the signal switching section 40 and is outputted to the delta/sigma modulator 9. The delta/sigma modulator 9 makes an analog image signal sequentially supplied from the signal switching section 40 undergo delta/sigma modulation, and the obtained 1-bit digital modulated signal is outputted to the signal processing section 20 and the delta/sigma modulation output terminal 2.

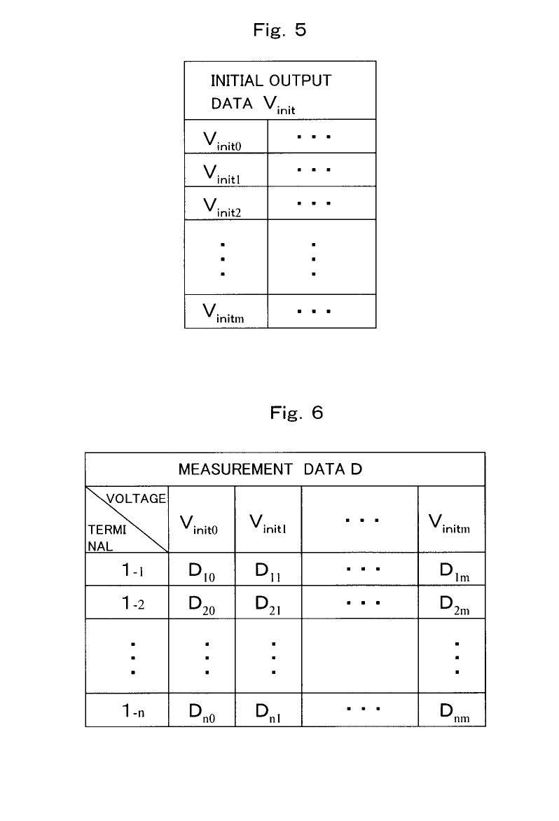

Next, a generating method of correction data will be described below. At the time of turning on a power source, the correction data storage circuit 10 stores no correction data therein. The correction signal processing circuit 11 establishes fixed initial output data Vᵢₙᵢₜ (Vᵢₙᵢₜ₀ to Vᵢₙᵢₜₘ) as illustrated in FIG. 5 in the initial course at power ON.

FIG. 5 is a view illustrating a configuration example of initial output data Vᵢₙᵢₜ₀ to Vᵢₙᵢₜₘ. As illustrated in FIG. 5, the initial output data Vᵢₙᵢₜ₀ to Vᵢₙᵢₜₘ as a reference digital signal are established within the range of the magnitude (voltage value) of a digital image signal inputted in the drive device 53. For the initial output data Vᵢₙᵢₜ₀ to Vᵢₙᵢₜₘ, values of a plurality of stages are set for each appropriate size. The initial output data Vᵢₙᵢₜ₀ to Vᵢₙᵢₜₘ may be stored in the correction data storage circuit 10 in advance. The quantity and intervals of the values of the initial output data Vᵢₙᵢₜ₀ to Vᵢₙᵢₜₘ may be arbitrarily set from the external control terminal (not illustrated) in accordance with obtained accuracy.

Next, the correction signal processing circuit 11 sequentially outputs the initial output data Vᵢₙᵢₜ₀ to Vᵢₙᵢₜₘ established as a reference digital signal into the analog signal output section 30. At this time, the reference digital signal is converted into an analog signal by the analog signal output section 30, and the analog signal is outputted from the respective drive transistors 4₋₁ to 4₋ₙ to the respective image output terminals 1₋₁ to 1₋ₙ. The analog signals outputted from the respective drive transistors 4₋₁ to 4₋ₙ are sequentially selected by the signal switching section 40 and are inputted into the delta/sigma modulator 9 for delta/sigma modulation. A produced 1-bit digital modulation signal is inputted into a selection signal processing circuit 11.

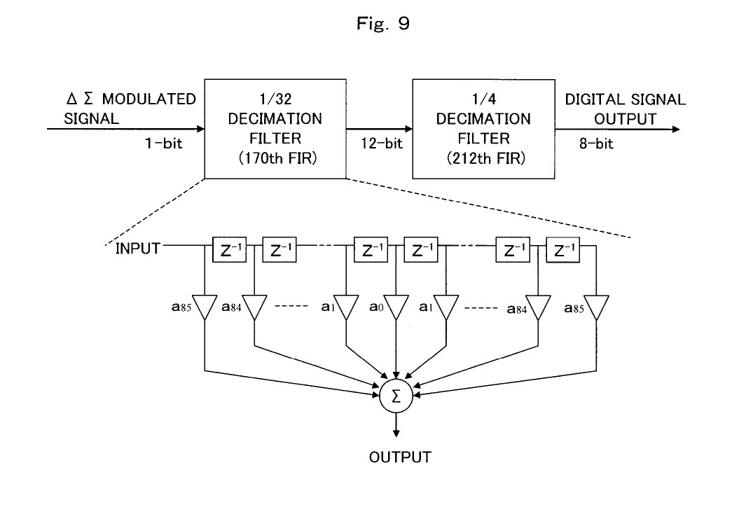

The correction signal processing circuit 11 includes a decimation filter and, by applying decimation processing to an inputted 1-bit digital modulated signal, the 1-bit digital modulation signal is demodulated into a digital signal having a predetermined number of bits (equivalent to a signal obtained by digitalizing output voltage of the image output terminal 1). Decimation processing can remove quantization errors to obtain a remarkably highly accurate digital voltage value. The decimation filter is constituted of, for example, an FIR filter illustrated in FIG. 9. A configuration for performing the decimation processing is not limited to the decimation filter, and may use DSP (Digital Signal Processor)or another one.

The correction signal processing circuit 11 receives a 1-bit digital modulated signal from the delta/sigma modulator 9 for demodulation, so that output voltage values D (Dₗ₀ to Dₙₘ) of the respective image output terminals 1₋₁ to 1₋ₙ corresponding to respective values of the initial output data Vᵢₙᵢₜ₀ to Vᵢₙᵢₜₘ are measured.

FIG. 6 is a view illustrating a configuration example of measurement data D (Dₗ₀ to Dₙₘ). As illustrated in FIG. 6, the measurement data Dₗ₀ to Dₙₘ are digital voltage values measured corresponding to the respective image output terminals 1₋₁ to 1₋ₙ by the delta/sigma modulator 9 when the initial output data Vᵢₙᵢₜ₀ to Vᵢₙᵢₜₘ are sequentially outputted into the analog signal output section 30 from the correction signal processing circuit 11. For example, when the initial output data Vᵢₙᵢₜ₀ is outputted into the analog signal output section 30, digital voltage values measured corresponding to the respective image output terminals 1₋₁ to 1₋ₙ by the delta/sigma modulator 9 are Dₗ₀ to Dₙ₀, and when the initial output data Vᵢₙᵢₜₘ is outputted into the analog signal output section 30, digital voltage values measured corresponding to the respective image output terminals 1₋₁ to 1₋ₙ by the delta/sigma modulator 9 are Dₗₘ to Dₙₘ.

The measurement data Dₗ₀ to Dₙₘ may be obtained by outputting the initial output data Vᵢₙᵢₜ₀ to Vᵢₙᵢₜₘ to the analog signal output section 30 from the correction signal processing circuit 11 over a plurality of times, and respectively averaging digital voltage values measured corresponding to the respective image output terminals 1₋₁ to 1₋ₙ by the delta/sigma modulator 9. For example, for the measurement data Dₗ₀, a voltage value of the image output terminal 1₋₁ is measured a plurality of times by outputting the initial output data Vᵢₙᵢₜ₀, therefore the average value is taken as the measurement data Dₗ₀. This averaging can restrain a disadvantage of random noise in the drive device 53 being included in the measurement data Dₗ₀ to Dₙₘ.

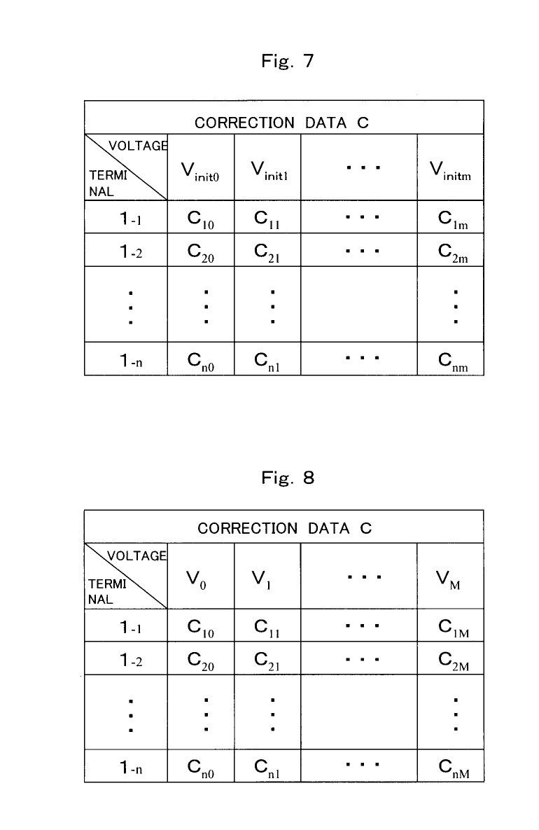

Next, the correction signal processing circuit 11 takes a difference between the initial output data Vᵢₙᵢₜ₀ to Vᵢₙᵢₜₘ and the measurement data Dₗ₀ to Dₙₘcorresponding to initial output data to produce correction data C (Cₗ₀ to Cₙₘ) and stores the produced data in the correction data storage circuit 10. FIG. 7 is a view illustrating a configuration example of correction data Cₗ₀ to Cₙₘ. As illustrated in FIG. 7, the correction data Cₗ₀ to Cₙₘ corresponds to a digital voltage value obtained by subtracting corresponding initial output data Vᵢₙᵢₜ₀ to Vᵢₙᵢₜₘ from the measurement data Dₗ₀ to Dₙₘ. For example, the data obtained by subtracting the initial output data Vᵢₙᵢₜ₀ from the measurement data Dₗ₀ is taken as the correction data C₁₀ relative to the image output terminal 1₋₁, when a digital signal of the same voltage as the initial output data Vᵢₙᵢₜ₀ is inputted into the drive circuit 53. Similarly, the data obtained by subtracting the initial output data Vᵢₙᵢₜₘ from the measurement data Dₙₘ is taken as the correction data Cₙₘ relative to the image output terminal 1₋ₙ when a digital signal of the same voltage as the initial output data Vᵢₙᵢₜₘ is inputted into the drive circuit 53.

The correction data C may be obtained from an approximated curve by making a change in the measurement data Dₗ₀ to Dₙₘ approximate to a change in the initial output data Vᵢₙᵢₜ₀ to Vᵢₙᵢₜₘ with a curve of the ‘k’th order (‘k’ is an arbitrary integer of 1 to (m+1) inclusive). For example, think of an approximation method with a curve of the secondary order (y=ax²+bx+c). In this case, for example, a change in the measurement data Dₗ₀ to Dₙₘ relative to a change in the initial output data Vᵢₙᵢₜ₀ to Vᵢₙᵢₜₘ in the image output terminal 1₋₁ can be expressed by the following equation:
Dₗ₀=a Vᵢₙᵢₜ₀²+b Vᵢₙᵢₜ₀+C
Dₗ₁=a Vᵢₙᵢₜ₁²+b Vᵢₙᵢₜ₁+C . . .
Dₗₘ=a Vᵢₙᵢₜₘ²+b Vᵢₙᵢₜₘ+C

The correction signal processing circuit 11 calculates three factors a, b, c from the above plurality of equations. If a change in the measurement data Dₗ₀ to Dₙₘ relative to a change in the initial output data Vᵢₙᵢₜ₀ to Vᵢₙᵢₜₘ is not approximated with the curve of the secondary order, the factor is obtained by approximating these changes with a curve of the tertiary order or order ‘k’ more than three.

For a change in the measurement data D₂₀ to Dₙₘ relative to a change in the initial output data Vᵢₙᵢₜ₀ to Vᵢₙᵢₜₘ in other image output terminals 1₋₂ to 1₋ₙ, the factors are obtained by approximating these changes with a curve of the ‘k’th order in the same way. The order ‘k’ of the approximated curve can be made different from each other for each of the image output terminals 1₋₁ to 1₋ₙ.

After an approximated curve is obtained for each of the image output terminals 1₋₁ to 1₋ₙ, the correction signal processing circuit 11 produces the correction data C (Cₗ₀ to C_{nM}) by substituting voltage values V_{O} to V_{M} of a plurality of stages into the equation of an approximated curve and subtracting the voltage values V_{O} to V_{M} from an approximation obtained by an calculation.

FIG. 8 is a view illustrating another configuration example of the correction data Cₗ₀ to C_{nM} obtained from an approximated curve in this way. As illustrated in FIG. 8, each of the correction data Cₗ₀ to C_{nM} corresponds to a digital voltage value obtained by subtracting input voltage values V_{O} to V_{M} from an approximate obtained from the approximated curve based on the measurement data Dₗ₀ to Dₙₘ. For example, a value obtained by respectively subtracting corresponding input voltage values V_{O} to V_{M} from approximates of which quantity is M and which is obtained from the measurement data Dₗ₀ to Dₗₘ of which quantity is m is correction amount C_{l0 to C}_{lM} for the image output terminal 1₋₁ when a digital signal of the same voltage as voltage values V_{O} to V_{M} is inputted into the drive circuit 53. Similarly, a value obtained by respectively subtracting corresponding input voltage values V_{O} to V_{M} from approximates of which quantity is M and which is obtained from the measurement data Dₙ₀ to Dₙₘ of which quantity is m in the same way is correction amount Cₙ₀ to C_{nM} for the image output terminal 1₋ₙ when a digital signal of the same voltage as voltage values V_{O} to V_{M} is inputted into the drive circuit 53.

In this case, input voltages V_{O} to V_{M} set within the range of the magnitude (a voltage value) of a digital image signal inputted into the drive device 53, and the number and the interval thereof can be arbitrarily set from an external control terminal (not illustrated) in accordance with desired accuracy. By setting in m<M, the resolution of the correction data can be increased and more highly accurate correction can be performed. If the quantity of the initial output data Vᵢₙᵢₜ₀ to Vᵢₙᵢₜₘ is increased from the beginning, measurement requires much time. However, by reducing the quantity of the initial output data Vᵢₙᵢₜ₀ to Vᵢₙᵢₜₘ and obtaining approximates of which quantity is M larger than that of the initial output data by means of calculation, measurement time can be reduced.

FIG. 10 is a view illustrating an example of results of decimation processing and averaging processing of 1-bit digital modulated signal outputted from the delta/sigma modulator 9 with the correction signal processing circuit 11. In FIG. 10, a sample point of a 1-bit digital modulated signal before decimation is each point indicated by a dashed line in the time-base direction, and a sample point after decimation is each point indicated by an arrow.

A point indicated by “x” in FIG. 10 is a voltage value obtained by applying decimation and averaging processing to a delta/sigma modulated signal relative to an ideal linear input signal as illustrated FIG. 4A. This corresponds to a value of the initial output data Vᵢₙᵢₜ₀ to Vᵢₙᵢₜₘ. A point indicated by “∘” is a voltage value obtained by applying decimation and averaging processing to a delta/sigma modulated signal relative to a nonlinear input signal as illustrated FIG. 4B. This corresponds to a value of the measurement data Dₗ₀ to Dₗₘ, for example, on the image output terminal 1₋₁. A line-a and a line-b in FIG. 10 is an approximated curve obtained by approximating changes of voltage values indicated by “x” and “∘” respectively. A length of a line-c corresponds to a correction amount at one sample point after decimation. With the approximated curve, a sample point taking a correction amount does not always need to meet a point “x” and may be taken at an arbitrary position. (As described above, sample points of which quantity is M larger than ‘m’ may obtain correction data Cₗ₀ to C_{lM}.)

The line-a corresponds to a change in output voltage values in the case that there are no variances in electrical characteristics, therefore correction amounts are “0” s relative to all input voltage values. On the contrary, the line-b includes nonlinear variances. By making a correction with a correction amount indicated by the line-c, errors of output voltage values due to variances can be minimized.

As described above, when the size of a transistor is reduced, nonlinear variances occur in output voltage values of the respective image output terminals 1₋₁ to 1₋ₙ, however, by inputting the initial output data Vᵢₙᵢₜ₀ to Vᵢₙᵢₜₘ of a plurality of stages and obtaining the correction data C (Cₗ₀ to Cₙₘ or Cₗ₀ to C_{1M}) like this embodiment, this correction can be made with higher accuracy than linear correction using only offset and gain.

Generating the correction data in the above way can be performed even with the drive device 53 mounted on the liquid crystal display device S. In this case, errors due to variances in electrical characteristics of the TFT transistor and the capacitance of the display section 51 which is connected to the image output terminal 1 of the drive circuit 53 are reflected into an analog signal into the image output terminal 1, so that correction data are produced including errors due to variances in the display section 51.

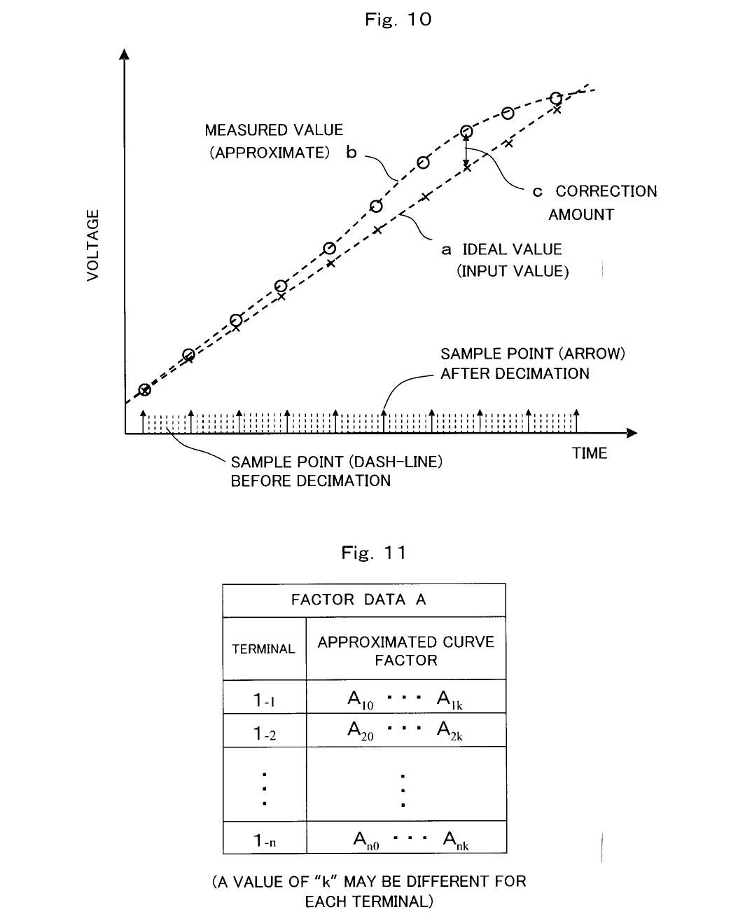

Here is described an example of storing correction data C in the correction data storage circuit 10, however, the factor data A of an approximated curve of the ‘k’th order may be stored as illustrated FIG. 11, and the correction data C may be calculated from the approximated curve of the ‘k’th order using the factor data A at every correction of a digital image signal. In the case, ‘k’ of the approximated curve can be made different from each other for each of image output terminals 1₋₁, to 1₋ₙ. Also, ‘k’ of the approximated curve can be made different from each other for every sample point interval indicated by a mark “∘” in FIG. 10 (an approximated curve different for each sample point is used). Moreover, an exponential function or a logarithmic function may be used as an approximated curve.

Repeated correction may be applied using the correction data C stored in the correction data storage circuit 10 for verification of a degree of correction. If errors do not converge within a predetermined range, accuracy may be lowered to a degree of which the errors can be converged, or a failure signal may be outputted.

In this verification processing, correction amount for the initial output data Vᵢₙᵢₜ may be further calculated based on the measurement data D obtained with the correction data C when the initial output data Vᵢₙᵢₜₜ are inputted, and newly calculated correction amount may be added to the produced correction data C for correction. If a degree of correction with the new correction data C obtained in this way does not converge within a predetermined convergence range, further correction of the correction data C may be performed.

As described above, usually, when a power supply is turned on, generating correction data is automatically performed. At the time of ordinary operation after generating correction data, the delta/sigma modulator 9 is controlled so as to come into no action. Furthermore, the analog switches 3₋₁ to 3₋ₙ of the signal switching section 40 are all in a non-selective state. At this time, a digital image signal inputted into the input latch circuit 8 is corrected by the correction signal processing circuit 11 based on correction data stored in the correction data storage circuit 10, and the corrected digital signal is outputted into the latch circuit 6. The corrected digital signal outputted from the latch circuit 6 is an input data into the D/A converter 5₋₁ to 5₋ₙ, and a voltage value of an analog image signal into the respective image output terminals 1_{-1 to 1}₋ₙ is controlled so as to be an optimum value.

Next, there is described a check and evaluation method for the drive device 53 and the display section 51. Check and evaluation of the drive device 53 itself are performed with the drive device 53 not mounted on the liquid crystal display device S (with the image output terminal 1 in an open state). For example, with an LSI of the drive device 53 composed on a wafer, the wafer is checked and evaluated.

FIG. 12 is a view illustrating a configuration example of a test system in checking and evaluating a wafer. The test system illustrated in FIG. 12 is constituted of a personal computer 90 for performing data processing, a digital type of simplified tester 91, a probe card 92, and a prober 93. The simplified tester 91 is constituted of, for example, a digital oscilloscope or a logic analyzer with a smaller measurement jitter than a clock cycle of the delta/sigma modulator 9.

The simplified tester 91, fitted with decimation filter, demodulates a 1-bit digital modulated signal inputted from the delta/sigma modulator 9 through the delta/sigma modulation output terminal 2 into a digital signal of predetermined number of bits (equivalent to a digitalized output voltage of the image output terminal 1) by means of decimation processing. The decimation processing can remove quantization errors and provides remarkably highly accurate digital voltage value. The decimation filter is constituted of, for example, an FIR filter as illustrated in FIG. 9. A configuration for performing the decimation processing is not limited to this configuration and may use a DSP or another similar configuration.

In checking and evaluating the drive device 53 using a test system configured in this way, some terminals including the delta/sigma modulation output terminal 2 are connected to a needle 92a of the probe card 92. The correction data for correcting errors due to variances in the electrical characteristics of respective transistors in the drive circuit 53 are generated in advance and are written in the correction data storage circuit 10.

First, a predetermined test pattern is inputted through the input latch circuit 8 of the drive device 53. A digital image signal of a test pattern inputted into the input latch circuit 8, after being corrected by the correction data in the signal processing section 10, is converted into an analog image signal by the D/A converter 5. The analog image signal is inputted into the delta/sigma modulator 9 through the drive transistor 4 and the signal switching section 40. A 1-bit digital modulated signal produced here is outputted into the simplified tester 91 from the delta/sigma modulation output terminal 2. The digital signal outputted from the delta/sigma modulation output terminal 2 can be set so as to be inputted into the simplified tester 91 in series or in parallel in accordance with the specification of the drive device 53.

The simplified tester 91 can receive a 1-bit digital modulated signal outputted from the delta/sigma modulation output terminal 2 through the probe card 92. The simplified tester 91 displays a pulse waveform of the 1-bit digital modulated signal inputted from the delta/sigma modulation output terminal 2 through the probe card 92 so as to be observed on a display unit. Moreover, digital signal processing such as demodulation processing is applied to the pulse waveform to measure the demodulated digital voltage value.

At this time, if the measured voltage value is deviated from a voltage value to be outputted (a voltage value of a test pattern) by at least a predetermined value (if correction is not sufficiently performed by correction data), the drive device 53 is determined as an inferior component. When it is within a correctable range even if the measured voltage value deviates, the drive device 53 is determined to be usable. The delta/sigma modulator 9 itself may have some malfunction, however, a delta/sigma modulated signal is not outputted or a waveform pulse abnormally goes wrong. So observation of such states indicates whether or not the drive device 53 should be handled as an inferior component.

For comparison to the test system according to this embodiment described above, a conventional test system will now be described. FIG. 18 is a view illustrating a frame configuration of a conventional test system. FIG. 18 illustrates a configuration example of the test system for checking and evaluating a drive LSI configured on a wafer. The test system roughly consists of a work station 100, a tester body 101, a test head 102, a probe card 103, and a prober 104. The probe card 103 is disposed with a plurality of needles 103a.

In a semiconductor circuit which outputs an image signal with multiple pins represented by a drive LSI of a display device, its quantity which permits simultaneous measurement of output values is limited to the quantity of the needles 103a of the probe card 103. Since test cost is proportional to test time per LSI, the test cost increases if the number of pins becomes larger than the number of the needles 103a. To restrain the test cost, the test system corresponding to the multiple pins for simultaneously measuring the output values of the multiple pins is required.

In the test system illustrated in FIG. 18, if the needles 103a of which quantity corresponds to that of output terminals (pins) of a drive LSI are arranged on the probe card 103, a measurement circuit or a signal output circuit can be used per pin of the drive LSI. However, in recent times, there are some probe cards 103 having the quantity of the needles 103a in excess of 1,000 pins. In the case of 1,000 pins, signals for 1,000 pins are exchanged between the tester body 101, the test head 102, and a probe card 103. Therefore, such a test system corresponding to multiple pins has a very large-scaled configuration.

With an advance of use of multiple pins and miniaturization of a drive LSI, a pitch between output terminals is further reduced, which makes it difficult to develop the probe card 103 having needles 103a corresponding to the narrow pitch, and to make a check itself, thus causing degradation in check reliability. If the probe card 103 corresponding to remarkably miniaturized pitches of the drive LSI cannot be manufactured, tests are required a plurality of times for one drive LSI, thus increasing test cost.

The prior art disclosed in Patent Document 3 includes separate output of signals outputted from a plurality of output terminals of a drive LSI to the outside from check terminals at a rate of one piece per a predetermined number of output terminals. According to Patent Document 3, between one check terminal and each of the predetermined number of output terminals, switchs are disposed to sequentially select an image signal appearing at the output terminal with a switching circuit and output the signal to the check terminal. Such a configuration permits to make a check with an image signal outputted from the check terminal without pressing a probe pin against all of a number of output terminals, thus accommodating use of super-multiple pins of the drive LSI.

However, the prior art disclosed in Patent Document 3 must use an analog tester as a check apparatus because an output signal from the check terminal is an analog signal. This causes a problem that a test system will become a large-scaled type. Moreover, there occurs a problem that highly accurate check and evaluation are difficult to make because a noise component is apt to invade into the output signal.

On the contrary, an example of this embodiment illustrated in FIG. 12 can make a check and evaluation with the probe card 92 having needles of a very small amount per drive LSI (10 needles in this case) without need for use of a probe card having a large amount of needles being used in a conventional test system. Checking a short/open of an electric wiring, a resistance value, capacitance value, transistor characteristics and so on can be performed using outputs from one delta/sigma modulation output terminal 2 without using outputs from the large amount of image output terminals 1.

According to this embodiment, a check and evaluation of analog image signals of super-multiple pins can be performed with a 1-bit digital signal line. Because a signal to be handled is a digital signal, a check and evaluation can be made with a very simplified tester 91 and a personal computer 90 without need for an analog type tester. Moreover, a check signal inputted into the simplified tester 91 is a digital signal, therefore highly accurate check and evaluation can be performed with few adverse effects of noises.

Checking and evaluating the drive device 53 can be performed with the drive device 53 mounted on the liquid crystal display device S. When the drive device 53 is mounted on the liquid crystal display device S, an error caused by variance in electrical characteristics of TFT transistors and capacitances provided in the display section 51 connected to the image output terminal 1 of the drive device 53 is reflected into a analog image signal. Accordingly, by fetching, as a check signal, a 1-bit digital modulated signal obtained by applying delta/sigma modulation to the analog image signal with the delta/sigma modulator 9, the display section 51 can be also checked and evaluated.

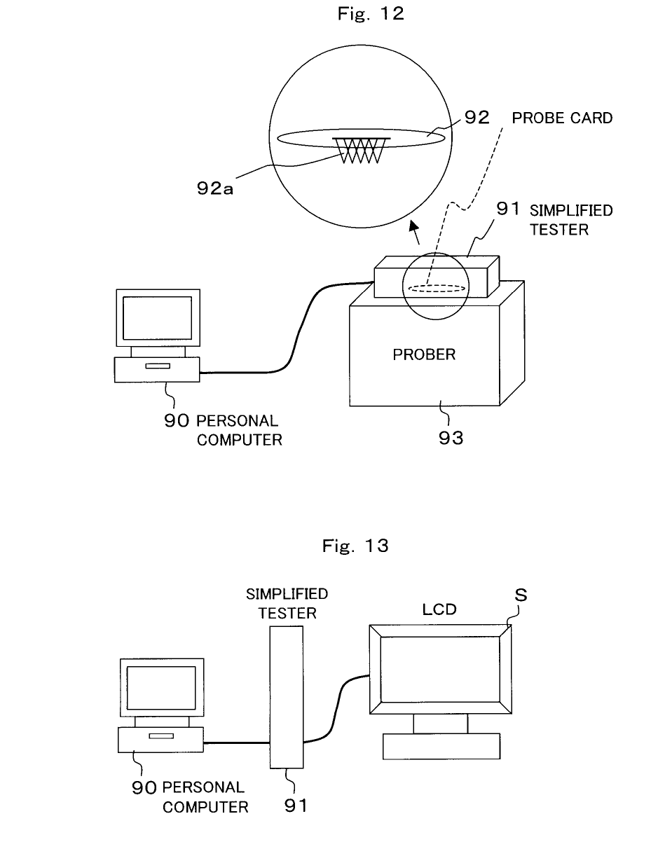

FIG. 13 is a view illustrating a configuration example of a test system in checking and evaluating the liquid crystal display device S mounted with the drive device 53. In checking and evaluating the liquid crystal display device S, correction data for correcting errors caused by variances in electrical characteristics of respective transistors within the drive device 53 as well as variances in electrical characteristics of TFT transistors or capacitances within the display section 51 are generated in advance and stored in the correction data storage circuit 10 of the drive circuit 53.

As illustrated in FIG. 13, checking and evaluating the liquid crystal display device S can be performed using the simplified tester 91 and the personal computer 90. A 1-bit digital modulated signal produced by the delta/sigma modulator 9 when a test pattern is inputted into the input latch circuit 8 needs only to be inputted into the simplified tester 91 from the delta/sigma modulation output terminal 2. At this time, if a voltage value to be measured based on the 1-bit digital modulated signal in the simplified tester 91 deviates from a voltage value to be originally outputted beyond a predetermined value, the liquid crystal display device S is determined as an inferior component. Even if the measured voltage value deviates, the liquid crystal display device S is determined as be usable when the deviation is within a correctable range.

With the drive device 53 mounted on the liquid crystal display device S as illustrated in FIG. 13, for example, by producing a pulse signal with the signal processing section 20 and outputting the pulse signal to the image output terminal 1 through the latch circuit 6, the D/A converter 5 and the drive transistor 4, the pixel capacitance of the display section 51 can be measured. By giving a pulse signal to the image output terminal 1 and measuring transient characteristics thereof with the delta/sigma modulator 9, variance in a product (time constant) of the capacitance and resistance in the display section 51 connected to the respective image output terminals 1₋₁ to 1₋ₙ can be measured. In this case, if an time interval to be measured is short, a clock speed of the delta/sigma modulator 9 is changed.

Substantially as described above, the drive device 53 according to this embodiment can convert each of analog image signals outputted from the plurality of image output terminals 1₋₁ to 1₋ₙ into a 1-bit digital modulated signal with the delta/sigma modulator 9, and can output the converted signal to the correction signal processing circuit 11 and the delta/sigma modulation output terminal 2 by only one electric wire. Thus, a smaller number of wirings can reduce manufacturing cost and undersize the drive device 53.

This embodiment can improve the correction accuracy of the digital image signals. In other words, because the delta/sigma modulator 9 is mounted inside the identical semiconductor chip to that of the drive device 53, a disadvantage of signal accuracy being degraded by noises can be reduced as compared to a case where an analog signal is outputted to the outside of the semiconductor chip for A/D conversion.

In constructing the drive device 53 by simply disposing the A/D converter in place of the delta/sigma modulator 9 so that a digital output thereof is supplied to the correction signal processing circuit 11, the accuracy of a digital image signal feedback-inputted into the correction signal processing circuit 11 is fixed by the accuracy of the A/D converter. On the contrary, the drive device 53 according to this embodiment, using the delta/sigma modulator 9, is not limited to the number of bits of the A/D converter, thus improving flexibility of correction data calculation. Moreover, this embodiment is structured so that a clock speed of the delta/sigma modulator 9 can be changed setting. Accordingly, by setting the clock speed of the delta/sigma modulator 9 at a high speed, time resolution can be increased to increase an S/N ratio of a 1-bit digital modulated signal, thus obtaining highly accurate correction data.

This embodiment can improve check accuracy. That is, for the number of the needles of the probe card, the number of the needles corresponding to the number of several output pins including the delta/sigma modulation output terminal 2 is sufficient. This permits to increase a pitch of the probe pin and complete connection to the delta/sigma modulation output terminal 2. Furthermore, a signal outputted from the delta/sigma modulation output terminal 2 is a digital signal, which can reduce a disadvantage of signal accuracy being degraded more significantly than a case where an analog signal is outputted, thus performing highly accurate check and evaluation.

Because the drive device 53, using the delta/sigma modulator 9, is structured so that a clock signal can be changed setting, the drive device 53 is not limited to the number of bits, unlike the case where an A/D converter is simply used, thus obtaining highly accurate check signal. That is, by changing a clock speed of the delta sigma modulator 9, a 1-bit digital modulated signal in accordance with check accuracy can be detected by an external check apparatus. Moreover, by setting the clock speed of the delta/sigma modulator 9 at a high speed to increase time resolution, thus increasing a S/N ratio of a check signal.

Furthermore, this embodiment can simplify a structure of the check apparatus. That is, for the number of the needles of the probe card, as described above, the number of the needles corresponding to the number of several output pins including the delta/sigma modulation output terminal 2 is sufficient. A signal outputted from the delta/sigma modulation output terminal 2 is a digital signal, which can simplify measures against signal degradation and noises and eliminate need for a large-scaled a check apparatus consisting of an expensive analog tester.

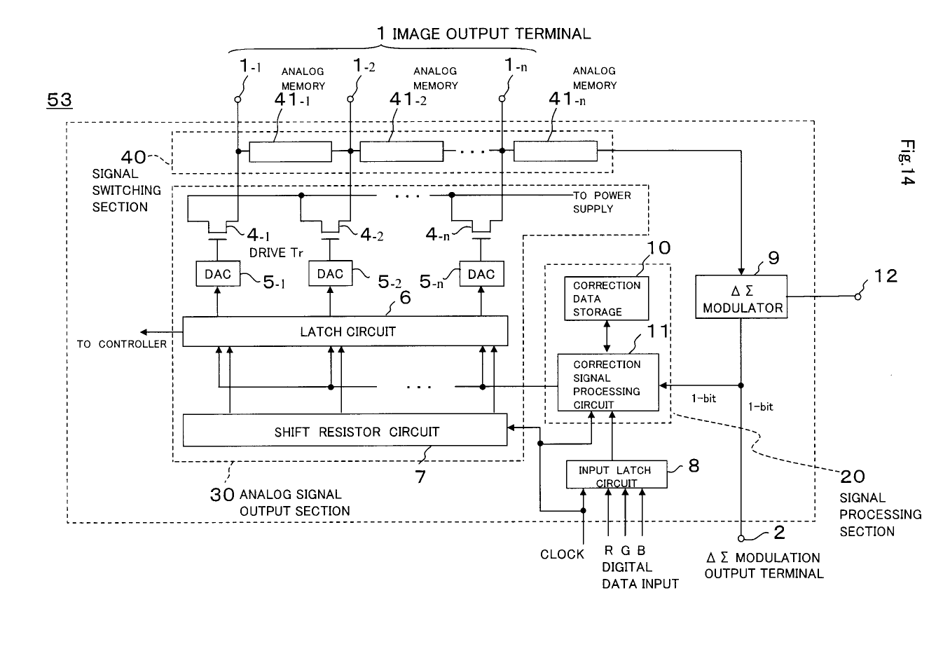

The embodiment described above explains an example using the analog switch 3 constituted of a transistor and so on as the signal switching section 40, but is not limited to the example. For example, as illustrated in FIG. 14, an analog memory 41 (41₋₁ to 41₋ₙ) may be used as the signal switching section 40. This permits an analog image signal outputted from the respective image output terminals 1₋₁ to 1₋ₙ to be selectively inputted into the delta/sigma modulator 9. In this case, a voltage follower circuit may be also used in place of the drive transistors 4 (4₋₁ to 4₋ₙ).

In the foregoing embodiment, an output from the latch circuit 6 is outputted to the image output terminal 1 through the D/A converter 5 and the drive transistor 4, but is not limited to the example. For example, as illustrated in FIG. 15, an analog image signal may be outputted to the image output terminal 1 through a plurality of analog signal switching devices (multiplexers) 32 (32₋₁ to 32₋ₙ) connected to the gradation voltage source 31.

In the case where the drive device 53 is constructed, D/A conversion using the gradation voltage source 31 and the analog signal switching device 32 is performed as follows. That is, a digital image signal inputted into the input latch circuit 8 is transmitted to the correction signal processing circuit 22, where correction is made based on correction data C stored in the correction data storage circuit 21, and the corrected digital signal is then outputted to the latch circuit 6. From the latch circuit 6, the corrected digital signal is outputted to analog signal switching devices 32₋₁ to 32₋ₙ in accordance with the respective image output terminals 1₋₁ to 1₋ₙ. The gradation voltage of a value corresponding to the corrected digital signal is supplied from the gradation voltage source 31 to analog signal switching devices 32₋₁ to 32₋ₙ and is outputted to the image output terminals 1₋₁ to 1₋ₙ.

In the case of an example illustrated in FIG. 15, the correction signal processing circuit 22 generates correction data for correcting errors due to variances in respective gradation voltages V₁ to Vᵢ of the gradation voltage source 31 and correction data for correcting errors due to variances in the respective analog signal switching devices 32₋₁ to 32₋ₙ, and stores them in the correction data storage circuit 21. The correction signal processing circuit 22 corrects variances in the gradation voltages V₁ to Vᵢ (global correction) and corrects variances between the image output terminals 1₋₁ to 1₋ₙ relative to digital image signals supplied from the input latch circuit 8 (mis-match correction). By correcting the gradation voltage source 31, variances in the gradation voltages V₁ to Vₗ which are deviations common to the plurality of image output terminals 1₋₁ to 1₋ₙ can be corrected.

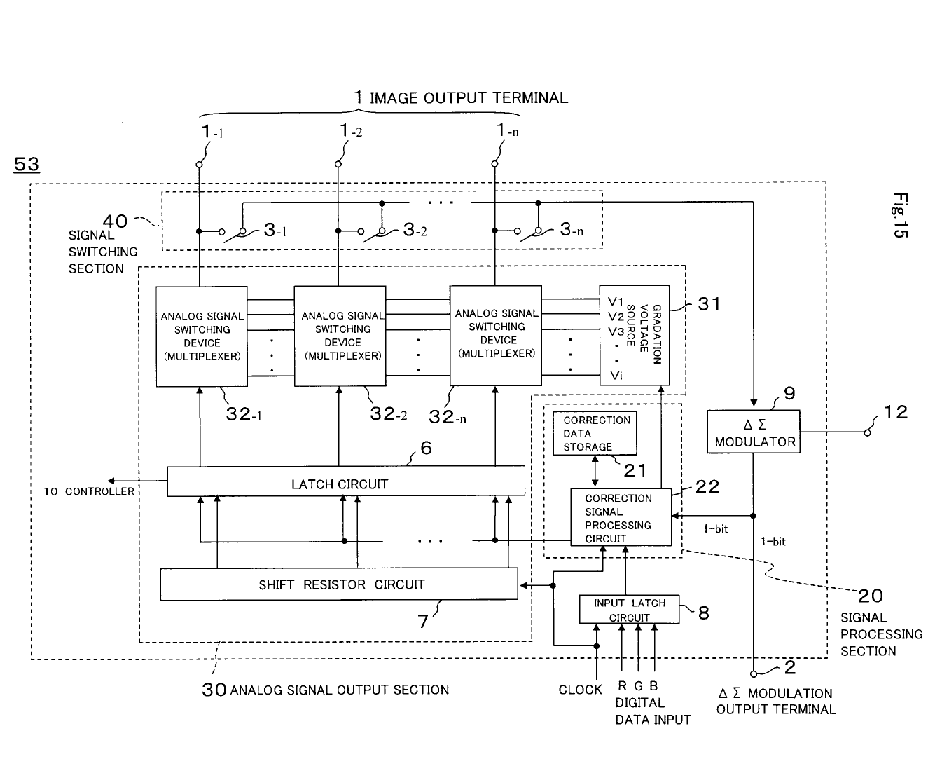

FIG. 16A and 16B are a view of a configuration example of measurement data obtained for generating correction data in constructing the drive device 53 as illustrated in FIG. 15. FIG. 16A shows measurement data Dₗ₀ to Dₙₘ measured by the delta/sigma modulator 9 in generating correction data for performing mis-match correction. The measurement data are obtained in the same way as for the measurement data Dₗ₀ to Dₙₘ shown in FIG. 6.

FIG. 16B shows measurement data Dₗ₀′ to D₁ᵢ′ measured by the delta/sigma modulator 9 in generating correction data for global correction. As shown in FIG. 16B, the measurement data Dₗ₁′ to Dₗᵢ′ for global correction are digital voltage values measured by delta/sigma modulating an analog signal outputted to, for example, an image output terminal 1₋₁ with the delta/sigma modulator 9 when initial output data V_{grad1} to D_{gradi} (an ideal value of gradation voltage) of a plurality of stages are sequentially outputted to the analog signal output section 30 as a reference digital signal from the correction signal processing circuit 22. The image output terminal 1₋₁ is used herein, but any of the other image output terminals 1₋₂ to 1₋ₙ may be used. Respective voltage values measured with the plurality of image output terminals 1₋₁ to 1₋ₙ may be averaged.

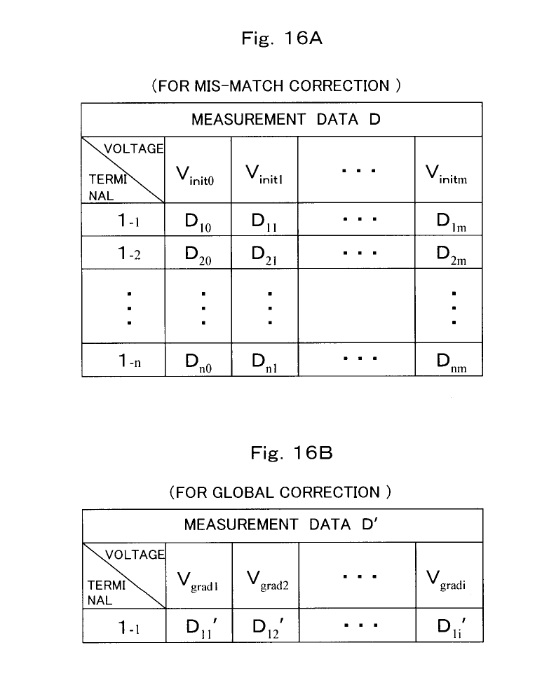

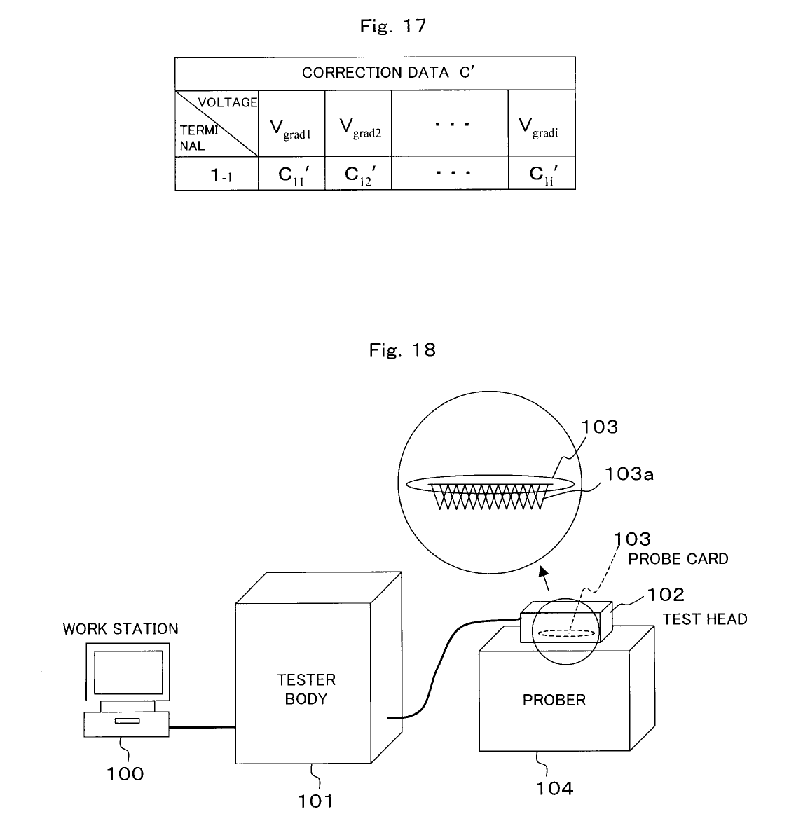

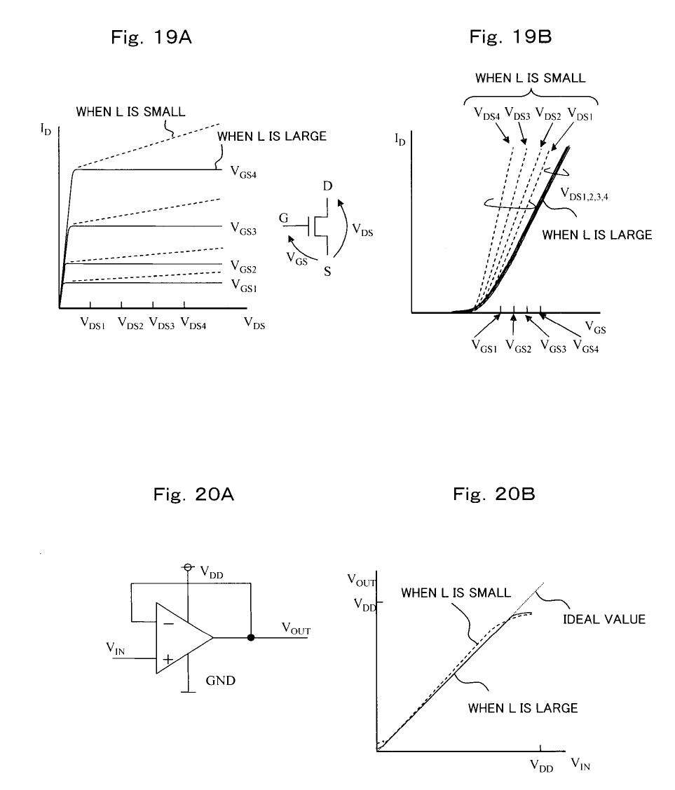

The correction signal processing circuit 22 calculates correction data C shown in FIG. 7 or FIG. 8 by obtaining an approximated curve or without obtaining an approximated curve based on the measurement data Dₗ₀ to Dₙₘ for mis-match correction shown in FIG. 16A or. And by taking a difference between the measurement data Dₗ₁′ to D₁ᵢ′ for global correction shown in FIG. 16B and the initial output data V_{grad1} to D_{gradi}, the correction data C′ shown in FIG. 17 is calculated. For the correction data C′ for global correction as well, an approximated curve may be obtained from the measurement data Dₗ₁′ to D₁ᵢ′ in the same way as for the correction data C for mis-match correction to calculate the correction data C′ based on the approximated curve.

For the correction data C, C′, it is preferable to previously obtain the correction data C′ for global correction and subsequently obtain the correction data C for mis-match correction with the corrected gradation voltages V₁ to Vᵢ. Repeated operations of calculations of the correction data C′ for global correction and the correction data C for mis-match correction may be performed. This can improve accuracy of both the correction data C, C′. The correction signal processing circuit 22 stores the correction data C, C′ obtained in this way in the correction data storage circuit 21. Global correction is made based on the stored correction data C′ and mis-match correction is made based on the correction data C.

In the foregoing embodiment, a signal outputted through the delta/sigma modulator 9 is an analog image signal to be outputted from the image output terminal 1, but is not limited to the analog image signal. This embodiment may be configured so as to output an analog signal supplied from another analog circuit connected to the drive device 53 or an analog signal to be outputted to another analog circuit as a digital signal through the delta/sigma modulator 9.

Furthermore, in the foregoing embodiment, there is an example in which the embodiment is applied to the voltage drive type liquid crystal display S, but the embodiment may be applied to a current drive type organic EL display device. Also, the embodiment may be applied to other display devices such as a plasma display and surface-conduction electron-emitter display (SED).

As many apparently widely different embodiments of the present invention can be without departing from the spirit and scope thereof, it is to be understood that the invention is not limited to the specific embodiments thereof except as defined in the appended claims.

### INDUSTRIAL APPLICABILITY

The present invention is applicable to a display device drive device having a great many analog output terminals like LSI for driving a display device such as a liquid crystal device, an organic EL display device, a plasma display and a surface-conduction electron-emitter display (SED), a display device using the drive device and a check method for the drive device or display device.

What is claimed as new and desired to be protected by Letters Patent of the United States is:

1. A display device drive device, having a plurality of output terminals and outputting analog signals from the plurality of output terminals, comprising:
a signal processing section for inputting digital signals corresponding to the plurality of output terminals and correcting each of the digital signals in accordance with correction data corresponding to the magnitude of the signal to output a digital correction signal;
an analog signal output section for producing an analog signal based on the digital correction signal outputted from the signal processing section and outputting the analog signal to each of the plurality of output terminals;
a signal switching section which is connected to the plurality of output terminals and sequentially selects the analog signal from the analog signal output section; and
a delta/sigma modulation section for applying delta/sigma modulation to the analog signal selected by the signal switching section and outputting a 1-bit digital modulated signal subjected to the delta/sigma modulation to the signal processing section;
wherein the signal processing section includes a function of sequentially outputting a reference digital signal having a plurality of stages of magnitudes to the analog signal output section, inputting the 1-bit digital modulated signal corresponding to the reference digital signal from the delta/sigma modulation section for demodulation and calculating the correction data based on the demodulated signal and the reference digital signal, and a function of a correction based on the correction data.

2. The display device drive device according to claim 1; the analog signal output section comprising:
a plurality of D/A converters for respectively converting digital signals corresponding to the plurality of output terminals to analog signals.

3. The display device drive device according to claim 1; the analog signal output section comprising:
a plurality of analog signal switching devices for respectively outputting gradation voltage based on digital signals corresponding to the plurality of output terminals; and
a gradation voltage source for supplying gradation voltage to the plurality of analog signal switching devices.

4. The display device drive device according to claim 3, wherein:
the signal processing section is configured so as to calculate correction data for gradation voltage correction based on the demodulated signal relative to the reference digital signal having the plurality of stages of magnitudes, and
the gradation voltage source is configured such that it can regulate the gradation voltage based on the correction data for gradation voltage correction calculated by the signal processing section.

5. The display device drive device according to claim 1, wherein:
the signal processing section creates an approximated curve based on a change in the demodulated signal relative to the reference digital signal having the plurality of stages of magnitudes and calculates the correction data based on the approximated curve.

6. The display device drive device according to claim 4, wherein:
the signal processing section creates an approximated curve based on a change in the demodulated signal relative to the reference digital signal having the plurality of stages of magnitudes and calculates the correction data for gradation voltage correction based on the approximated curve.

7. The display device drive device according to claim 1, wherein:
the signal processing section calculates the correction data using an average value of demodulated signals for a plurality of times produced by outputting the plurality of times the reference digital signal having the plurality of stages of magnitudes.

8. The display device drive device according to claim 1, wherein the correction data are respectively calculated in accordance with the plurality of output terminals.

9. The display device drive device according to claim 1, wherein the signal switching section is constituted of a switch consisting of a transistor, or an analog memory.

10. The display device drive device according to claim 1, wherein the delta/sigma modulation section is configured such that it can change setting of a clock speed.

11. The display device drive device according to claim 1, further comprising delta/sigma modulation output terminal capable of outputting 1-bit digital modulated signal from the delta/sigma modulation section.

12. The display device drive device according to claim 1, wherein the signal processing section, the analog signal output section, the signal switching section and the delta/sigma modulation section are disposed on the identical semiconductor IC.

13. A display device equipped with a drive device according to claim 1.

14. A check method for a drive device for outputting analog signals from a plurality of output terminals or a display device equipped with the drive device, the method comprising:
a test pattern input process of inputting a test pattern into the drive device;
an analog signal acquisition process of sequentially acquiring an analog signal produced in accordance with the test pattern by sequentially switching a signal switching device connected with a plurality of output terminals of the drive device;
a delta/sigma modulation process of delta/sigma-modulating an analog signal acquired by the analog signal acquisition process;
a delta/sigma modulated signal output process of outputting a 1-bit digital modulated signal produced by the delta/sigma modulation process from a check terminal to the outside; and
a check process of acquiring a 1-bit digital modulated signal outputted from the check terminal and performing a check or evaluation.

15. The check method for a drive device or a display device according to claim 14, further comprising:
a process of correcting the test pattern by correction data after the test pattern input process,
wherein the analog signal acquisition process acquires an analog signal produced in accordance with a test pattern corrected by the correction data.

16. The check method for a drive device or a display device according to claim 15; further comprising, before the test pattern input process: sequentially inputting a reference digital signal having a plurality of stages of magnitudes to the drive device, sequentially acquiring an analog signal produced in accordance with the inputted reference digital signal with the signal switching device, delta/sigma-modulating the analog signal to acquire a 1-bit digital modulated signal, and calculating the correction data in accordance with the reference digital signal having the plurality of stages of magnitudes and a demodulated signal of the 1-bit digital modulated signal.
